(19) United States
(12) Patent Application Publication
(10) Pub. No.: US 2010/0002465 A1
(43) Pub. Date: Jan. 7, 2010

(54) LIGHT EMITTING DIODE DEVICE AND BACKLIGHT MODULE USING THE SAME

(75) Inventors: JIAN SHIHN TSANG, TAIPEI COUNTY (TW); IRENE CHEN, TAOYUAN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/496,969

(22) Filed: Jul. 2, 2009

(30) Foreign Application Priority Data
Jul. 7, 2008 (TW) 097125501

(51) Int. Cl. F21V 7/04; H01L 33/00

(52) U.S. Cl. 362/612; 257/100; 257/E33.059

(57) ABSTRACT

A light emitting diode (LED) device comprises a substrate, an LED chip and an encapsulation body. The LED chip is mounted on the substrate, and the encapsulation body is overlaid on the LED chip and the substrate. The encapsulation body includes a light output surface. The light output surface can uniformly diffuse emission light over a wide angle in a first direction and concentrate the emission light in a second direction perpendicular to the first direction.

### BACKGROUND OF THE INVENTION

1. Field of the Invention

The present invention relates to a light emitting diode device and a backlight module, and relates more particularly to a light emitting diode device with improved light emission distribution and a backlight module using the same.

2. Description of the Related Art

Because light emitting diodes (LED) have characteristics such as low power consumption, high conversion efficiency and extended lifetimes, and they can exhibit excellent color performance when used in backlight modules, the application of light emitting diodes in display devices has become a focus of much research in recent years.

Backlight modules are categorized according to the position of the module, including direct-lit backlight modules and edge-lit backlight modules. At present, the major apparatuses using liquid crystal displays are notebook computers and other liquid crystal display screens, and the requirements of the backlight modules used in these apparatuses are light weight, small volume, and thin profile. Of the two types of modules, the edge-lit backlight modules can best meet these requirements.

FIG. 1 is a cross sectional view showing a light emitting diode package disclosed in Taiwan Patent Publication No. 200733425. The LED package 10 includes a housing 10 and a seating recess 11 formed on the upper portion of the housing 10; an LED 12 seated on the bottom of the seating recess 11; and a lens 13 disposed on the upper side of the seating recess 11. The light emitted from the LED 12 passes through the lens 13 having a convex surface that can redirect light over large angles so that the redirected light can laterally emit. However, such an LED 12 is suitable for direct-lit backlight modules, not for edge-lit backlight modules.

In addition, as shown in FIG. 2, Taiwan Patent Publication No. 200512500 discloses an LED package suitable for an edge-lit backlight module. The LED package 20 includes a base 21, a light emitting diode 22, and an encapsulation resin 23. The encapsulation resin 23 encases the light emitting diode 22 and is formed to have a light output surface (not shown) similar to a hemispherical surface, and a diffraction grating 24 including a plurality of grooves is disposed on the light output surface to similarly increase the refraction angle of emitted light. Although such a hemispherical light output surface can distribute light uniformly, the hemispherical light output surface cannot concentrate light in the thickness-wise direction (i.e. the direction perpendicular to the light output surface) to meet the requirements of an edge-lit backlight module, and therefore light beams having a large emitting angle relative to a central axis cannot be directed into the interior of the backlight from the side thereof. Further, the groove structure of the diffraction grating 24 is unfavorable to a press-molding process. Specifically, melt molding material cannot easily fill the grooves completely, and during the demolding operation, the protruding portions between the grooves can easily be damaged.

Taiwan Patent No. 1287126 provides an LED package for a direct-lit backlight module, and a light guide plate mated with the LED package and having a concavity formed on a bottom surface, for accommodating the LED package. The point light source of the LED package is received within the concavity, and a semi-transparent and semi-reflective film is further disposed between the light guide plate and the point light source. With the characteristics of the penetration ratio of light of the semi-transparent and semi-reflective film that is inversely proportional to the distance between the point light source and the film, the light entering into the light guide plate can be diffused as uniformly as possible. However, such a semi-transparent and semi-reflective film is not easy to manufacture, and it may absorb a portion of passing light so as to lower light utilization efficiency.

U.S. Pat. No. 6,953,952 proposes a semiconductor device adapted for edge-lit backlight module and packaged using a lead-frame. Although the semiconductor device is shaped to be tightly embedded into a side of a light guide plate, the process using a lead-frame to package a semiconductor device is complex and results in higher manufacturing cost. Furthermore, the lengths of light paths in different directions are significantly different so that light passing through different paths may encounter different amounts of phosphorous particles. Consequently, the uniformity of light from the light output surface may be poor.

In summary, the manufacture of a light emitting diode having improved light emission efficiency remains an urgent research target in the lighting industry.

### SUMMARY OF THE INVENTION

The present invention proposes a light emitting diode device and a backlight module. The light emitting diode device has an outline configuration that can improve light emission distribution, and that can uniformly diffuse over a wide angle and concentrate emission light along two perpendicular directions. Furthermore, in a backlight module, light entering the light guiding plate of the backlight module increases such that the non-uniformity of light distribution at the light entrance side of the light guiding plate can be eliminated.

To solve the prior art issues, the present invention provides the following solution: a light emitting diode device comprises a substrate, a light emitting diode chip and an encapsulation body. The light emitting diode chip is mounted upon a surface of the substrate. The encapsulation body is coated on the light emitting diode chip and the substrate. The encapsulation body includes a light output surface, wherein the light output surface is parallel to the surface of the substrate, and the light output surface can uniformly diffuse emission light over a wide angle in a first direction and concentrate the emission light in a second direction perpendicular to the first direction, wherein the two directions perpendicular to the surface of the substrate.

The encapsulation body includes two shoulder portions respectively disposed on two ends of the light output surface.

The light output surface comprises at least one curved surface, and the curved surface is a semi-cylindrical surface, or the light output surface may comprise a plurality of continuously connected curved surfaces.

The light output surface includes a plurality of planes. The light output surface is a triangular prism with two adjacent inclines.

The distances between each position on the light output surface and the light emitting diode chip are approximately equal.

The light emitting diode device further comprises two end surfaces adjacent to the light output surface, and the two end surfaces are perpendicular to the surface of the substrate.

The light emitting diode device further comprises reflecting layers disposed on the two end surfaces.

The present invention provides a backlight module, which comprises a light emitting diode device and a light guiding plate. The light emitting diode device comprises a substrate, a light emitting diode chip and an encapsulation body. The light emitting diode chip is mounted upon a surface of the substrate. The encapsulation body is coated on the light emitting diode chip and the substrate. The encapsulation body includes a light output surface, wherein the light output surface is parallel to the surface of the substrate, and the light output surface can uniformly diffuse emission light over a wide angle in a first direction and concentrate the emission light in a second direction perpendicular to the first direction, wherein the two directions perpendicular to the surface of the substrate. A lateral side of the light guide plate includes at least one recess, wherein the recess can engage with the light output surface.

The light emitting diode device further comprises two shoulder portions respectively disposed on two ends of the light output surface.

The shape of the recess is complementary to the shape of the light output surface.

### BRIEF DESCRIPTION OF THE DRAWINGS

The invention will be described according to the appended drawings in which:

FIG. 1 is a cross sectional view showing a light emitting diode package disclosed in Taiwan Patent Publication No. 200733425;

FIG. 2 shows an LED package suitable for an edge-lit backlight module disclosed in Taiwan Patent Publication No. 200512500;

FIG. 3A is a perspective view showing a light emitting diode device according to the first embodiment of the present invention;

FIG. 3B is a cross section taken along line A-A in FIG. 3A;

FIG. 3C is a cross section taken along line B-B in FIG. 3A;

FIG. 4A is a perspective view showing a light emitting diode device according to the second embodiment of the present invention;

FIG. 4B is a cross section taken along line C-C in FIG. 4A;

FIG. 4C is a cross section taken along line D-D in FIG. 4A;

FIG. 5A is a perspective view showing a backlight module according to one embodiment of the present invention;

FIG. 5B is a perspective view showing a backlight module according to another embodiment of the present invention;

FIG. 6 is a perspective view of a light emitting diode chip according to the third embodiment of the present invention;

FIG. 7A is a perspective view of a light emitting diode chip according to the fourth embodiment of the present invention;

FIG. 7B is a perspective view of a light emitting diode chip according to the fifth embodiment of the present invention;

FIG. 8A is a perspective view of a light emitting diode chip according to the sixth embodiment of the present invention;

FIG. 8B is a perspective view of a light emitting diode chip according to the seventh embodiment of the present invention;

FIG. 9A is a perspective view of a light emitting diode chip according to the eighth embodiment of the present invention;

FIG. 9B is a perspective view of a light emitting diode chip according to the ninth embodiment of the present invention; and

FIGS. 10A and 10B show angular distributions of scattered light from a light emitting diode chip according to one embodiment of the present invention.

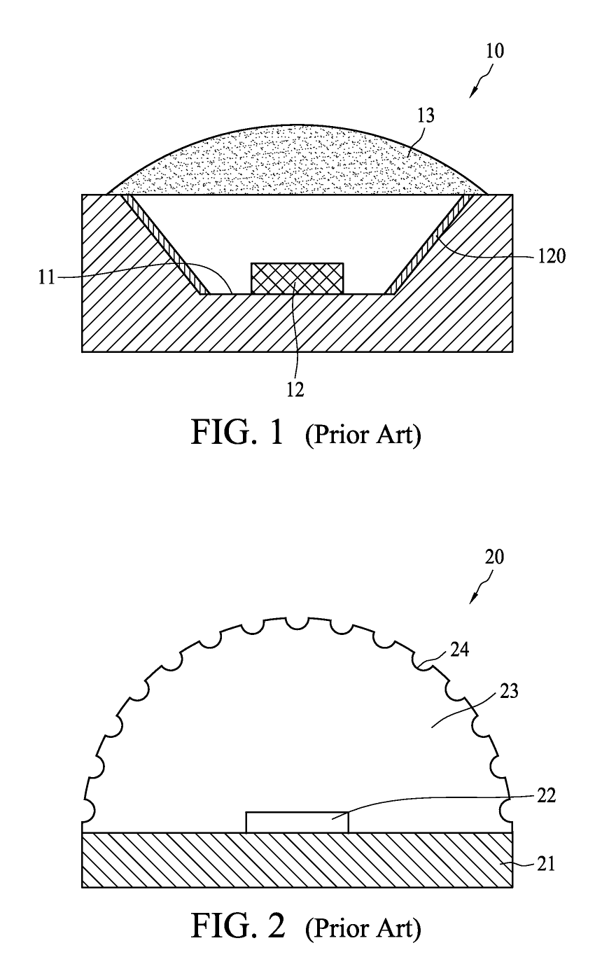

### DETAILED DESCRIPTION OF THE INVENTION

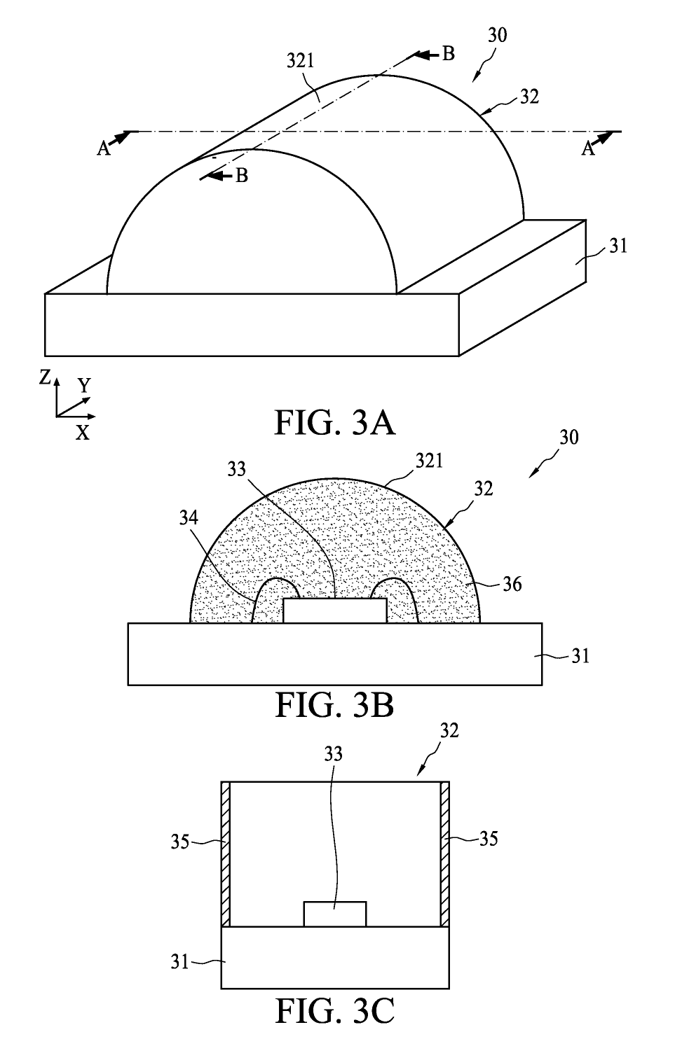

Referring to FIG. 3A, according to one embodiment of the present invention, the light emitting diode device 30 comprises a substrate 31 and an encapsulation body 32. The encapsulation body 32 has an upper surface that includes a non-planar light output surface 321. As shown in FIG. 3A, the semi-cylindrical light output surface 321 may tend to scatter emitted light at larger angles. In other words, light emitted from the light output surface 321 may become more uniform. Cross-sections of the encapsulation body 32 along the Y-axis direction parallel to the XZ plane are substantially identical, and two end surfaces of the encapsulation body 32 are also parallel to the XZ plane. Therefore, emission light is concentrated within a specified angle in the Y-axis direction.

FIG. 3B is a cross section taken along line A-A in FIG. 3A. The light emitting diode device 30 further comprises a light emitting diode chip 33 and at least one metal wire 34. The light emitting diode chip 33 is mounted on the surface of the substrate 31, and the encapsulation body 32 covers the light emitting diode chip 33 and the substrate 31. The metal wire 34 is configured to electrically connect the light emitting diode chip 33 to the substrate 31. In the encapsulation body 32, phosphorus particles 36 are evenly mixed. Light, emitted from a light-emitting region on the surface of the light emitting diode chip 33, penetrating through the light output surface 321 passes through paths having similar lengths in different directions such that the light propagating through each light path may encounter similar amounts of phosphorus particles. The semi-cylindrical light output surface 321 of the present invention can result in uniform light distribution. More specifically, the distance from every position on the light output surface 321 to the central position of the light emitting diode chip 33 is approximately equal.

FIG. 3C is a cross section taken along line B-B in FIG. 3A. The two end surfaces of the encapsulation body 32 can be coated with a reflective layer 35. Because the two end surfaces are planes perpendicular to the surface of the substrate 31, the view angle of the light emitted from the light emitting diode chip 33 along the Y direction can be further constrained.

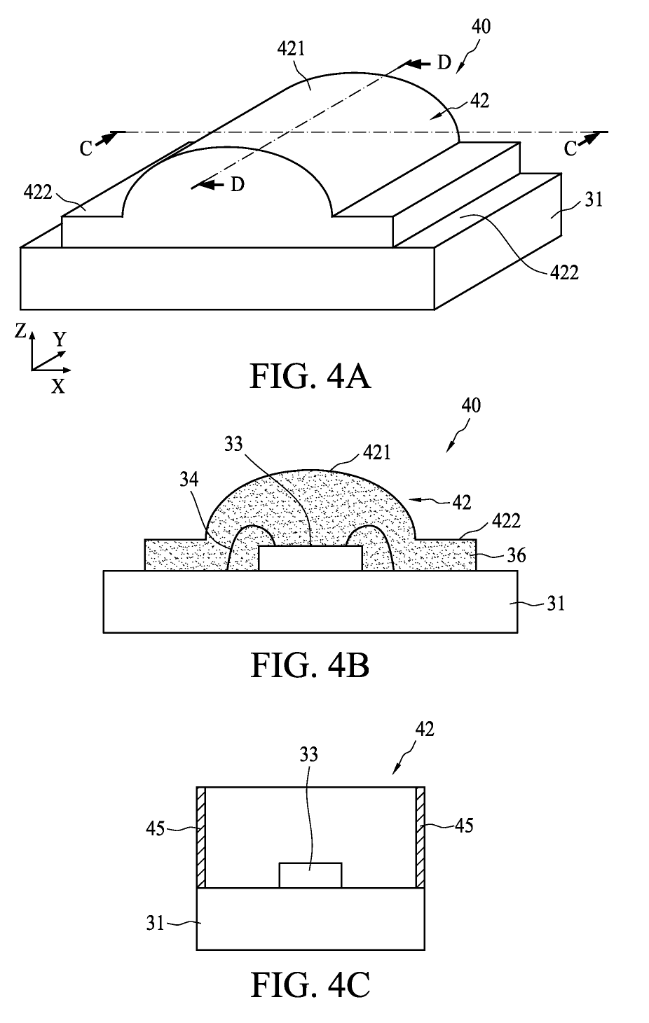

As shown in FIG. 4A, according to one embodiment of the present invention, the light emitting diode device 40 comprises a substrate 31 and an encapsulation body 42. The encapsulation body 42 has an upper surface that includes a non-planar light output surface 421. As shown in FIG. 4A, the light output surface 421 on the configuration of a semi-elliptical cylinder may tend to scatter emitted light at larger angles. In other words, light emitted from the light output surface 421 may become more uniform. Cross-sections of the encapsulation body 42 along the Y-axis direction parallel to the XZ plane are substantially identical, and two end surfaces of the encapsulation body 42 are also parallel to the XZ plane. Therefore, emission light is concentrated within a specified angle in the Y-axis direction. The encapsulation body 42 includes two shoulder portions 422 disposed on the two sides thereof respectively and configured to provide support for installation.

FIG. 4B is a cross section taken along line C-C in FIG. 4A. The light emitting diode device 40 further comprises a light emitting diode chip 33 and at least one metal wire 34. The light emitting diode chip 33 is mounted on the surface of the substrate 31, and the encapsulation body 42 covers the light emitting diode chip 33 and the substrate 31. The metal wire 34 is configured to electrically connect the light emitting diode chip 33 to the substrate 31. In the encapsulation body 42, phosphorus particles 36 are evenly mixed. Light, emitted from a light-emitting region on the surface of the light emitting diode chip 33, penetrating through the light output surface 421 passes through paths having similar lengths in different directions such that the light propagating through each light path may encounter similar amounts of phosphorus particles. The non-planar light output surface 421 of the present invention can result in uniform light distribution. More specifically, the distance from every position on the light output surface 421 to the central position of the light emitting diode chip 33 is approximately equal.

FIG. 4C is a cross section taken along line D-D in FIG. 4A. The two end surfaces of the encapsulation body 42 can be coated with a reflective layer 45. Because the two end surfaces are planes perpendicular to the surface of the substrate 31, the view angle of the light emitted from the light emitting diode chip 33 along the Y direction can be further constrained.

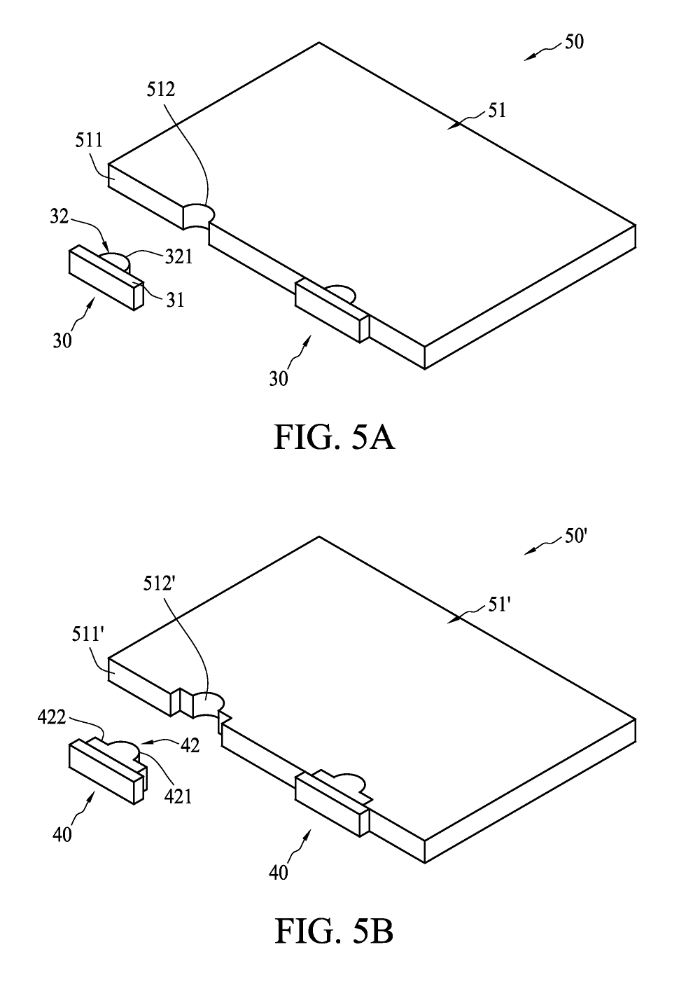

FIG. 5A is a perspective view showing a backlight module according to one embodiment of the present invention. The backlight module 50 comprises a plurality of light emitting devices 30 and a light guide plate 51, one lateral side 511 of which includes a plurality of recesses 512 each having a configuration complementarily mated with the outline of the light output surface 321 on an encapsulation body 32. Namely, the light output surface 321 can remain close to the interior of the respective recess 512 and the substrate 31 may also be firmly placed against the lateral side 511 at the same time.

FIG. 5B is a perspective view showing a backlight module according to another embodiment of the present invention. The backlight module 50′ comprises a plurality of light emitting devices 40 and a light guide plate 51′, one lateral side 511′ of which includes a plurality of recesses 512′ each having a configuration complementarily mated with the outline of the light output surface 421 and the shoulder portions 422 of an encapsulation body 42. Namely, the light output surface 421 and the shoulder portions 422 can remain close to the configuration of the respective recess 512′.

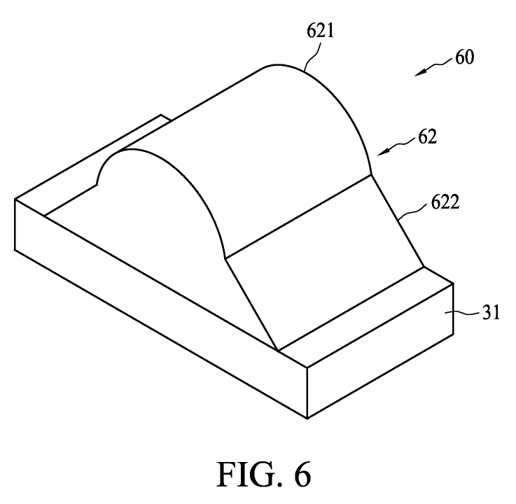

FIG. 6 is a perspective view of a light emitting diode chip according to another embodiment of the present invention. The light emitting diode chip 60 comprises a substrate 31 and an encapsulation body 62. The encapsulation body 62 has an upper surface that includes a non-planar light output surface 621. As shown in FIG. 6, the semi-cylindrical light output surface 621 may tend to scatter emitted light at larger angles. In other words, light emitted from the light output surface 621 may become more uniform. Two shoulder portions 622 with respective inclines are disposed correspondingly on the two sides of the encapsulation body 62 and are configured to provide support for installation.

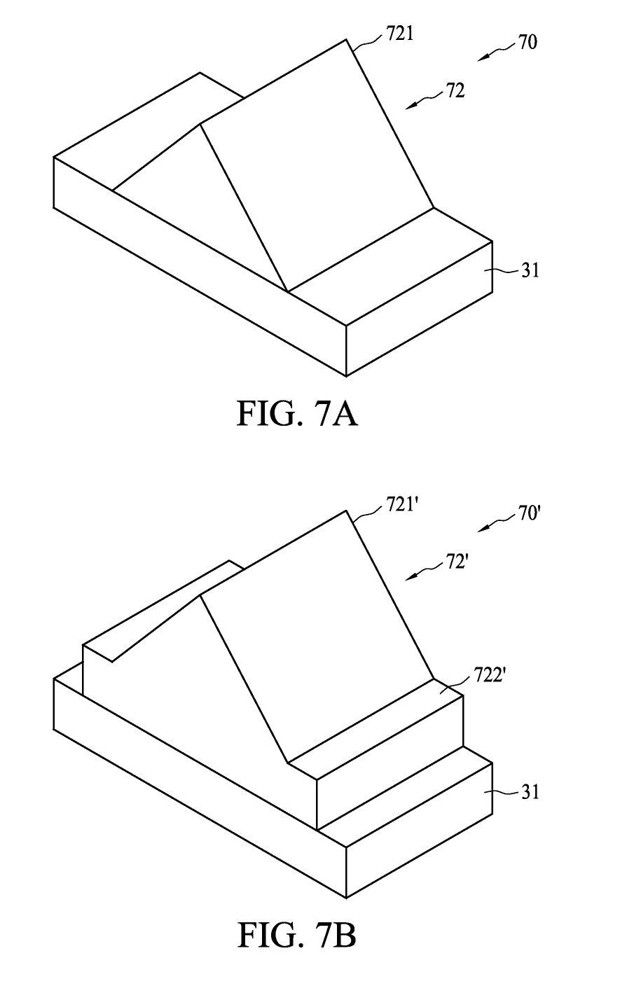

Compared to the embodiments in FIGS. 3A and 6, the light output surfaces 721 of the encapsulation body 72 of the light emitting diode chip 70 in FIG. 7A define a triangular prism-like shape, which has two inclines causing uniform distribution of emitted light. The encapsulation body 72 is attached to the surface of the substrate 31.

Referring to FIG. 7B, the light output surfaces 721′ of the light emitting diode chip 70′ define a triangular prism-like shape, and the two sides of the encapsulation body 72′ are disposed respectively with shoulder portions 722′. The encapsulation body 72′ is attached to the surface of the substrate 31.

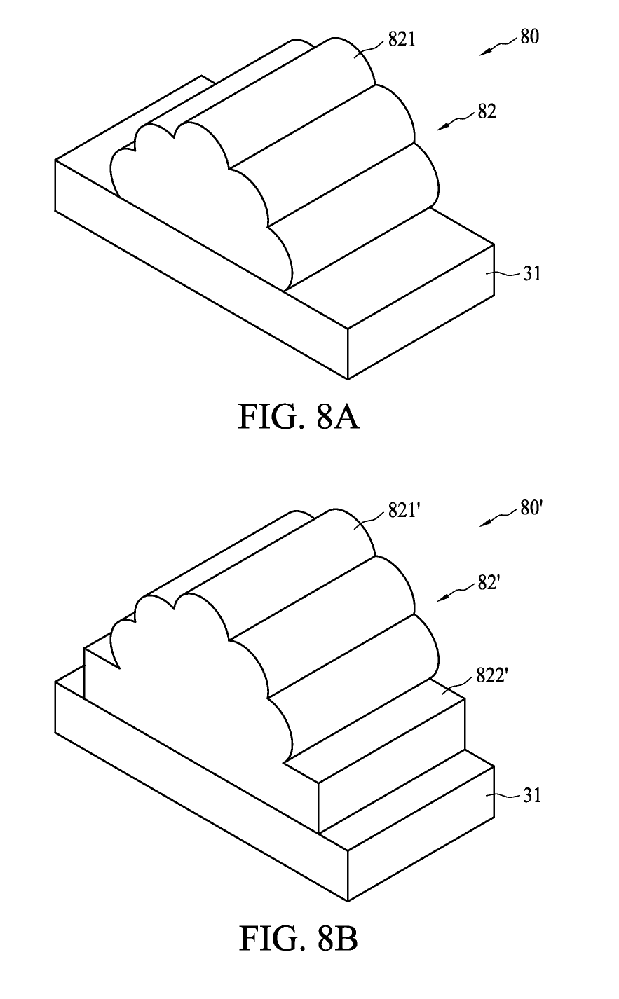

FIG. 8A is a perspective view of a light emitting diode chip according to the sixth embodiment of the present invention. The contour of the light emitting output surface 821 of the encapsulation body 82 of the light emitting diode chip 80 shown in the figure is composed of a plurality of continuously connected circular arcs, and the circular arc-shaped curve surfaces can uniformly distribute light over forward angles. The encapsulation body 82 is attached to the surface of the substrate 31.

Moreover, referring to FIG. 8B, the contour of the light emitting output surface 821′ of the light emitting diode chip 80′ is composed of a plurality of continuously connected circular arcs, and the two sides of the encapsulation body 82′ are respectively disposed with right-angle shoulder portions 822′, which are configured to provide support for installation. The encapsulation body 82′ is attached to the surface of the substrate 31.

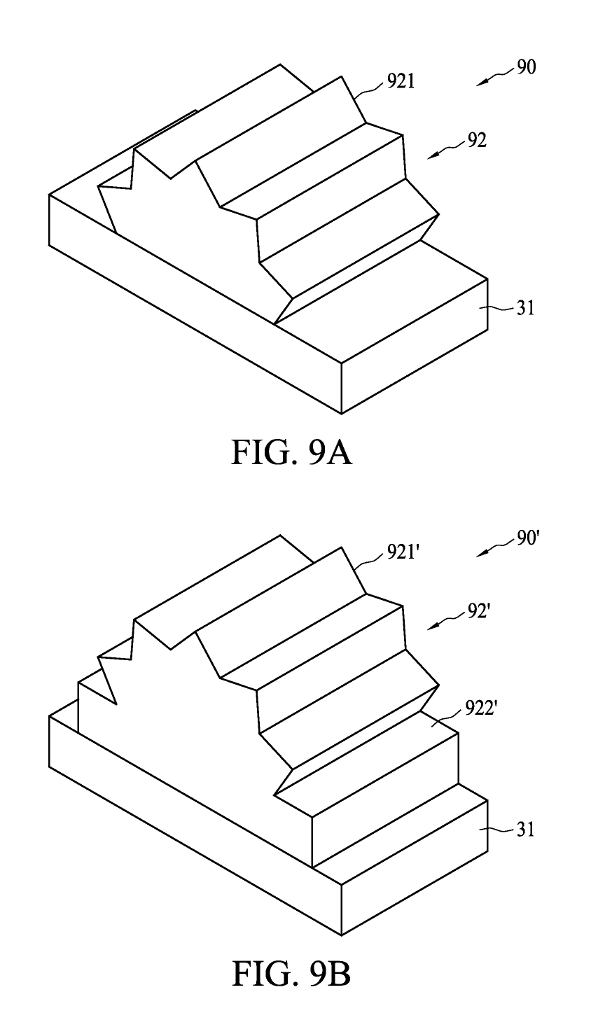

FIG. 9A is a perspective view of a light emitting diode chip according to the eighth embodiment of the present invention. The contour of the light emitting output surface 921 of the encapsulation body 92 of the light emitting diode chip 90 shown in the figure is composed of a plurality of continuously connected planes, the planes each having different inclined angles that can uniformly distribute light over forward angles. The encapsulation body 92 is attached to the surface of the substrate 31.

Referring to FIG. 9B, the contour of the light emitting output surface 921′ of the light emitting diode chip 90′ is composed of a plurality of continuously connected planes. The two sides of the encapsulation body 92′ are respectively disposed with right-angle shoulder portions 922′, which are configured to provide support for installation. The encapsulation body 92′ is attached to the surface of the substrate 31.

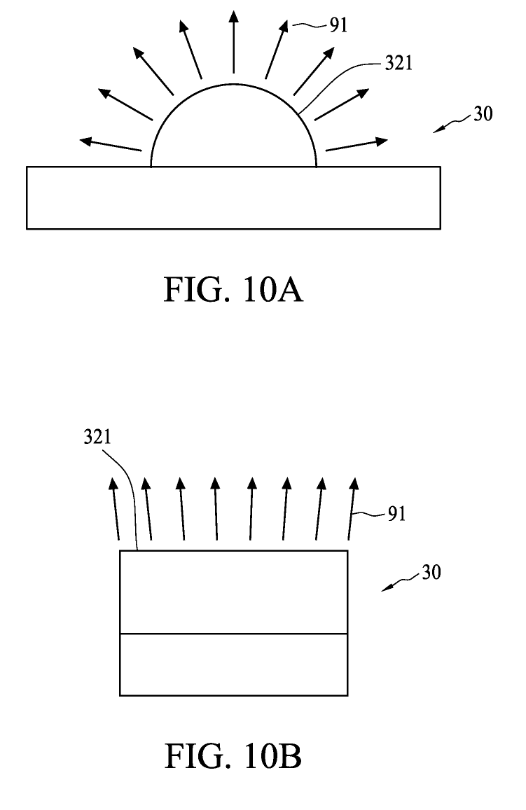

FIGS. 10A and 10B show angular distributions of scattered light from a light emitting diode chip according to one embodiment of the present invention. As shown in the figures, the light beam 91 passing through the light output surface 321 travels over a wider angle (about 90 degrees to 180 degrees), and the observed light distribution is uniform at every degree of angle. Compared to the curved surface in FIG. 10A, the light, as shown in FIG. 10B, emitted from the light output surface travels over a constrained angle (less than about 60 degrees).

The above-described embodiments of the present invention are intended to be illustrative only. Numerous alternative embodiments may be devised by persons skilled in the art without departing from the scope of the following claims.

What is claimed is:

1. A light emitting diode device, comprising:
a substrate;
a light emitting diode chip mounted upon a surface of said substrate; and
an encapsulation body coated on said light emitting diode chip and said substrate, and said encapsulation body including a light output surface, wherein said light output surface is parallel to said surface of said substrate, and said light output surface can uniformly diffuse emission light over a wide angle in a first direction and concentrate the emission light in a second direction perpendicular to the first direction.

2. The light emitting diode device as in claim 1, wherein said encapsulation body includes two shoulder portions respectively disposed on two ends of said light output surface.

3. The light emitting diode device as in claim 1, wherein said light output surface comprises at least one curved surface, and said curved surface is a semi-cylindrical surface.

4. The light emitting diode device as in claim 3, wherein said light output surface is formed by a plurality of curved surfaces.

5. The light emitting diode device as in claim 1, wherein said light output surface includes a plurality of planes.

6. The light emitting diode device as in claim 1, wherein said light output surface is a triangular prism with two adjacent inclines.

7. The light emitting diode device as in claim 1, wherein distances between each position on said light output surface and said light emitting diode chip are approximately equal.

8. The light emitting diode device as in claim 1, further comprising two end surfaces adjacent to said light output surface and reflecting layers disposed on said corresponding end surfaces, wherein said two end surfaces are perpendicular to said surface of said substrate.

9. The light emitting diode device as in claim 2, wherein said two shoulder portions are planes or inclines that are perpendicularly connected with each other.

10. A backlight module, comprising:
a light emitting device, comprising:
a substrate;
a light emitting diode chip being mounted upon a surface of said substrate; and
an encapsulation body coated on said light emitting diode chip and said substrate, said encapsulation body including a light output surface, wherein said light output surface is parallel to said surface of said substrate, whereby said light output surface can uniformly diffuse emission light over a wide angle in a first direction and concentrate the emission light in a second direction perpendicular to the first direction; and
a light guide plate including at least one recess into a lateral side of said light guide plate, wherein said recess can engage with said light output surface.

11. The backlight module as in claim 10, wherein said encapsulation body includes two shoulder portions respectively disposed on two ends of said light output surface.

12. The backlight module as in claim 10, wherein said light output surface includes at least one curved surface, and said curved surface is a semi-cylindrical surface.

13. The backlight module as in claim 10, wherein said light output surface is formed by a plurality of curved surfaces.

14. The backlight module as in claim 10, wherein said light output surface includes a plurality of planes.

15. The backlight module as in claim 10, wherein said light output surface is a triangular prism with two adjacent inclines.

16. The backlight module as in claim 10, wherein distances between each position on said light output surface and said light emitting diode chip are approximately equal.

17. The backlight module as in claim 10, further comprising two end surfaces adjacent to said light output surface and reflecting layers disposed on said corresponding end surfaces, wherein said two end surfaces are perpendicular to said surface of said substrate.

18. The backlight module as in claim 11, wherein said two shoulder portions are planes or inclines that are perpendicularly connected with each other.

19. The backlight module as in claim 11, wherein said shoulder portions is engageable with said recess of said light guide plate.

20. The backlight module as in claim 11, wherein shape of said recess is complementary to shape of said light output surface.
